(19) United States
(12) Patent Application Publication
(10) Pub. No.: US 2015/0024225 A1
(43) Pub. Date: Jan. 22, 2015

(54) SCREEN PRINTING FILM AND SURFACE MODIFICATION METHOD OF THE SAME

(71) Applicant: Industrial Technology Research Institute, Hsinchu (TW)

(72) Inventors: Yu-Ting Lin, New Taipei City (TW); Kun-Ping Huang, Miaoli County (TW); Chih-Chen Chang, New Taipei City (TW)

(73) Assignee: Industrial Technology Research Institute, Hsinchu (TW)

(21) Appl. No.: 14/105,089

(22) Filed: Dec. 12, 2013

(30) Foreign Application Priority Data
Jul. 22, 2013 (TW) 102126133

(51) Int. Cl. C23C 16/46; C23C 16/27; C23C 16/50; C23C 16/48; B41N 1/24; C23C 16/02; C23C 16/32

(52) U.S. Cl. CPC C23C 16/46; C23C 16/0209; C23C 16/27; C23C 16/32; C23C 16/481; C23C 16/482; B41N 1/247; C23C 16/50
USPC 428/500; 427/569; 427/558; 427/557; 427/577

(57) ABSTRACT

A screen printing film and a surface modification method of the same are provided. The method includes providing a substrate having a PVA film on at least one surface of the substrate. The surface of the substrate is modified by generating a heating source and a plasma source, wherein a heating temperature to the substrate is between 100° C. and 500° C. The step of generating the heating source may be prior to, after, or simultaneous with the step of generating the plasma source.

### CROSS-REFERENCE TO RELATED APPLICATION

This application claims the priority benefit of Taiwan application serial no. 102126133, filed on Jul. 22, 2013. The entirety of the above-mentioned patent application is hereby incorporated by reference herein and made a part of this specification.

### TECHNICAL FIELD

The disclosure generally relates to a screen printing film and a surface modification method of the same.

### BACKGROUND

The development of the technologies has brought fine screen printing to be a main manufacturing technology for printing silver electrode wires of solar panels. A screen printing film is a printing mask defining the patterns of the electrode wires. After laminating the screen printing films on the solar panels to be printed, and spreading slurries with conductive metals (usually containing silver), the printing of the electrode is complete. Furthermore, the screen printing films can be reused after scraping the residual slurries. This can be repeated until the slurries on the surface are difficult to be scraped off or the films are damaged.

The screen printing film may be made of a polymer film or a metal thin film. The metal thin film provides a good mechanical strength and multiple recycle times; but the manufacturing cost of the metal thin film is high. As for the polymer film, despite the low cost and low technology threshold, the slurries thereon are hard to remove due to the inherent hydrophilicity and the adhesion characteristics of the polymer films. The residual slurries lead to a decrease printing quality time after time. This consequently curtails the recycle time of polymer printing films. Accordingly, the overall manufacturing cost of the solar cell electrodes is bound to be increased. Recently, hydrophobic coatings have been introduced to improve the residual problems. But the wet swelling issue of polymer film, which cause the variation of pattern width and poor contact between screen film and solar cell, still hinder the polymer-based screen printing from a mature manufacture technology to solar cells.

Some specific polymer films, such as polyvinyl alcohol (PVA) which composed with long-chain polymers with hydroxyl groups (—OH), absorb the water from the slurries significantly due to the hydrogen bonds between hydroxyl and water. PVA with smaller molecular weight which has higher solubility to water, is even vulnerable to wet sewlling. As a result, both the abated tension and the deformed pattern decrease the printing qualities.

### SUMMARY

One of the present embodiments comprises a surface modification method of a screen printing film. The method includes: providing a substrate in which at least one surface of the substrate is a polyvinyl alcohol (PVA) film, generating a heating source, and generating a plasma source for deposition of a hydrophobic film to modify the surface of the substrate. The heating temperature to the substrate is between 100° C. and 500° C.

Another of the present embodiments comprises a screen printing film. The screen printing film is surface-modified by using the above-mentioned method. A main component of the screen printing film is hydroxyl group-free PVA.

Several exemplary embodiments accompanied with figures are described in detail below to further describe the disclosure in details.

### BRIEF DESCRIPTION OF THE DRAWINGS

FIG. 1 is a process flow of the surface modification of the screen printing film according to an embodiment of the disclosure.

FIG. 2 is an infrared absorption spectrum of the untreated PVA film and the heating-modified PVA film of the example.

FIG. 3 is a schematic diagram showing water droplets contact angle tests of the untreated PVA film and the screen printing film of the example.

FIG. 4 is a diagram illustrating the variations in weight at different stages of the untreated PVA film and the screen printing film of the example.

DETAILED DESCRIPTION OF DISCLOSED EMBODIMENTS

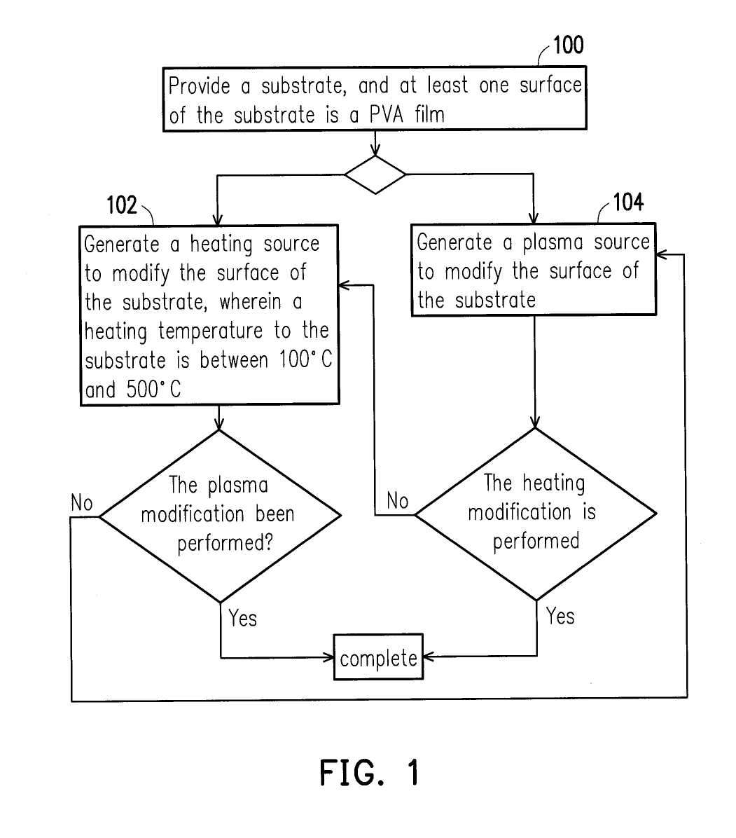

FIG. 1 is a process flow of the surface modification of the screen printing film according to an embodiment of the disclosure.

Please refer to FIG. 1. In step 100, the substrate is provided, wherein at least one surface of the substrate is a PVA film

Then, either step 102 or step 104 may be processed, or the step 102 and the step 104 may be processed simultaneously. In the step 102, a heating source is generated to modify the surface of the substrate that is the PVA film, wherein a heating temperature to the substrate is between 100° C. and 500° C., for example. A heating time of the heating source is, for example, between 1 second and 300 seconds, and a heating frequency thereof may be between 1 time and 20 times. For example, the heating source such as an infrared lamp, ultraviolet (UV) light or the like may be used to perform a short-time local exposure several times. Optionally, the heating source may be contact heating, such as a plate heater which performs instantaneous local heating. Moreover, in step 102, the microwave or the radio frequency electromagnetic wave may be utilized to perform the electromagnetic heating with stainless steel meshes which is attached or embedded in the screen film. Through step 102, the PVA film is thermally decomposed or cross-linked without melting or burning the fastening glue which is generally disposed around the screen printing film, so as to achieve the modification and non-absorbent properties of the PVA film. It is found by measurements that the main component of the PVA film modified through step 102 is hydroxyl group-free PVA.

In step 104, a plasma source is generated to modify the surface of the substrate that is the PVA film, so as to carry out improvements in hydrophobicity and water resistance of the screen printing film. After step 104, a hydrophobic film is deposited on the surface of the PVA film. Thus, the surface of the PVA film has properties of hydrophobicity, non-adhesive and non-water-swelling. For example, the water contact angle of the surface becomes greater, that is, the contact angle of the screen printing film with water may be greater than 100 degrees and/or less than 150 degrees. The plasma source is, for example, electron cyclotron resonance (ECR) or capacitance-coupled plasma (CCP). A pressure of the plasma source is between 10⁻⁴ Torr and 1 Torr, for example. A reaction gas of the plasma source is at least one, for example, selected from the group consisting of fluorocarbon, hydrocarbon, oxygen and inert gases. The reaction gas may be single gas or a combination of two or more gases. Moreover, for example, a flow of the inert gases shows a specific ratio with respect to the flow of the other reaction gases. For example, the flow of the inert gases accounts for between 10% and 75% based on a total flow of the reaction gases.

The plasma coverage area of the plasma source is at least 0.1 m² or more, for example, between 0.1 m² and 4 m². In the embodiment, to accomplish the large area plasma source as above, a multi-source ECR (MECR) consists of multiple microwave panes may be used to assemble a large area microwave apparatus (referring to the apparatus of TW201230886). Accordingly, each plasma excitation units can be made to generate non-interactive plasma sources independently, so as to achieve the large area plasma with high density and high uniformity. Furthermore, the problems of high costs for the large area panes (such as quartz glass) and being vulnerable to deformation or fragmentation by compression of atmospheric pressure can be solved.

Additionally, the plasma modification performed in step 104 may also be composed of two plasma treatments. For example, a plasma-assisted smooth coating which improves the adherence between the PVA film and a plasma-assisted hydrophobic coating of the surface hydrophobic treatments may be performed in tandem. The above-mentioned plasma assisted hydrophobic coating may be a diamond-like coating (α-C:H) by using room temperature plasma-enhanced chemical vapor deposition. Since the diamond-like film is a compact carbon stacking, it is difficult for water molecules to permeate into, and its surface is smooth with low surface adhesion energy. The hydrocarbon gases may be used as the reaction gas for the plasma source, wherein the hydrocarbon gases include but are not limited to CH₄, C₂H₂, C₂H₄, C₃H₆, C₃H₈ and the like.

On the other hand, in the above-mentioned plasma assisted hydrophobic coating, various plasmas may be used to form the fluorocarbon film (α-C:F). the fluorocarbon film may be formed by using fluorocarbon gases, wherein the fluorocarbon gases include but are not limited to CF₄, C₂F₆, C₃F₈ and the like, an appropriate amount of O₂ with CF₄, or an appropriate amount of the hydrocarbon gas with CF₄, in which the ratio of C to F is about between 2 and 3. As for the plasmas used in the above-mentioned plasma-assisted hydrophobic coating, the capacitance-coupled plasma (CCP), the inductance-coupled plasma (ICP), the surface wave plasma (SWP) or the electron cyclotron resonance (ECR) are included, wherein the SWP and the ECR are more suitable as means for the coating of the fluorocarbon film. In the embodiment, for example, through above two plasma treatments, the surface of the screen printing film having the hydrophobicity can be achieved. Furthermore, even when the surface of the screen printing film is wetted by water droplets, the droplets are easily run off with gravity, which benefits the removal of the printing slurries. In step 104, the coating rate can be accelerated and the density of the coating products can be enhanced if further applying a DC or RF bias during the plasma modification.

Additionally, in the embodiment, effect of forming the coatings simultaneously on both the front surface and the back surface of the screen printing film can be achieved by using the ECR plasma. Since the ECR plasma is operated under a relatively low-pressured (˜mTorr) environment, the diffusion capacity of the plasma is strong, and the plasma ions and radicals can even diffuse through few-micron pores. Therefore, through the diffusion of the plasma ions and radicals into the back surface of the screen printing film, the hydrophobic film can be formed on both sides. Accordingly, in comparison with conventional plasma treatments, it can solve the problem of the hydrophobic film depositing only on the front surface of the screen printing film, causing the back surface of the screen printing film to be susceptible to the adhesion of the slurries and hard to remove therefrom.

In the embodiment, step 102 of generating the heating source may be performed prior to or after step 104 of generating the plasma source. In order to prevent the surface plasma coating from being damaged by volatile gases during modification by heating, it is better to perform step 102 first.

The following are some experiments to verify the performances of the disclosure, but the scope of the disclosure is not limited thereto.

### EXAMPLE

First, the side glue is protected with an Al/PTFE frame, and the screen printing film is a PVA film disposed therein. Then, an exposure from the heating source of the infrared lamps is performed on the PVA film, wherein the exposure is performed 4 to 5 times and about 2.5 seconds each time, and a power of each infrared lamp is 1300 W.

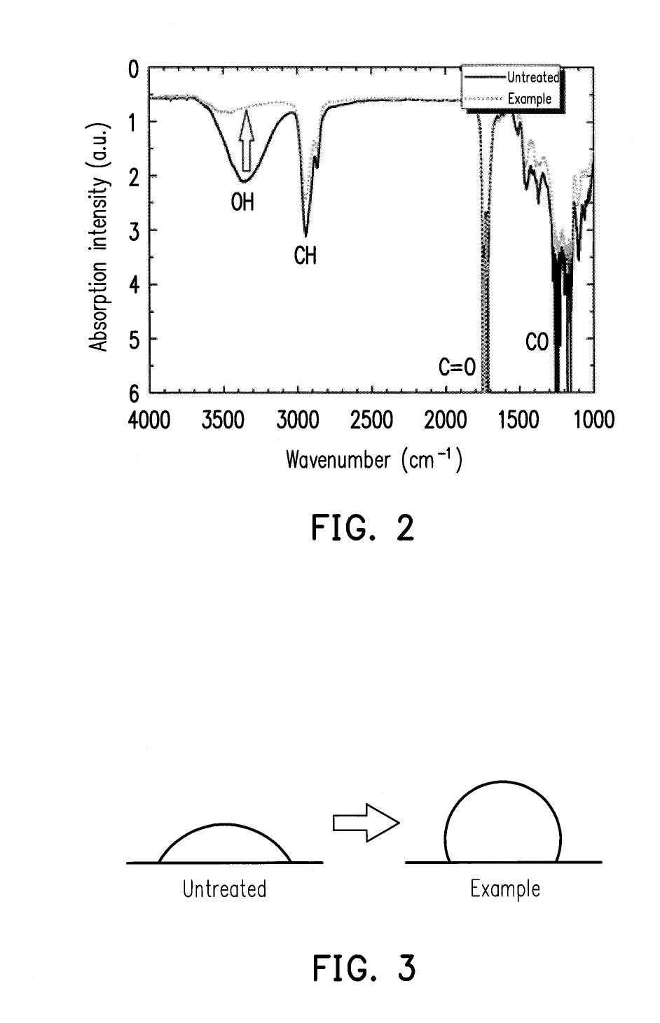

Next, Fourier transform infrared spectroscopy (FTIR) measurement is performed to the heating-modified PVA film and the infrared absorption spectrum shown in FIG. 2 is obtained. FIG. 2 shows that only the OH absorption of the heating-modified PVA film is significantly reduced, which means the OH groups in the molecules are strongly diminished. Therefore, through the measurements, the heating-modified PVA film is found to be hydroxyl-free PVA.

Then, a series of the plasma modifications is performed to the heating-modified screen printing film. Detailed processes are as follows.

First, the vacuum (<2×10⁻⁵ Torr) is built. Then, C₂H₂ and Ar are used as the reaction gases of the plasma source under the pressure of 3.5 mTorr, and the step of plasma modification is performed for about 1 minute. The flow ratio of C₂H₂ to. Ar is 1:1, and the microwave power of each of the plasma sources is 1800 W. According to the step, the diamond-like film (α-C:H) may be formed on the surface of the PVA film.

Thereafter, CF₄, C₂H₂ and Ar are used as the reaction gases of the plasma source under the pressure of 5.8 mTorr, and the step of plasma modification is performed for about 1 minute. The flow ratio of CF₄, C₂H₂ and Ar is 3:2:3, and the microwave power of each of the plasma sources is 1800 W. Through the step, the fluorocarbon (α-C:F) may be formed on the surface of the PVA film. The resulting surface of the screen printing film is a hydrophobic multilayer film including a plasma-coated fluorocarbon film and a plasma-coated diamond-like film.

After that, the resulting screen printing film is measured by the following tests.

Water Droplets Contact Angle Test

The result from the water droplets contact angle test is as shown in FIG. 3. The contact angle of the untreated PVA film with water is about 60 degrees, but the contact angle of the modified screen printing film of the example with water is about 114 degrees. Accordingly, the modified screen printing film of the example is proved to be able to achieve the hydrophobic effect.

Weight Variation Measurement

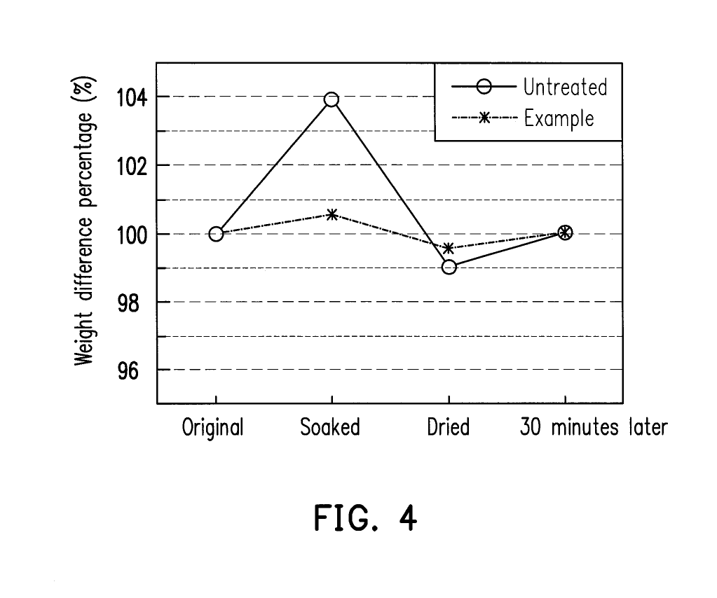

The original state is made 100% by weight. Weights at different stages of the untreated PVA film and the screen printing film of the example are measured, and the ratios of the weight differences are calculated as shown in FIG. 4. According to FIG. 4, the amount of water absorbed after the modified screen printing film of the example is immersed is far below then that of the untreated PVA film, which proves that the modified screen printing film of the example can achieve the non-absorbent property.

In summary, the disclosure uses the heating sources and the plasma sources to perform the surface modifications to the PVA film which is utilized for the screen printing films of the solar cells, and thus it can have the properties of hydrophobicity, low adhesion, non-absorbent, non-swelling, and non-softening. According to the disclosure, the screen printing quality of silver electrode wires can be greatly improved, and the production cost of the solar cells can be effectively and indirectly reduced.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A surface modification method of a screen printing film, comprising:
providing a substrate, wherein at least one surface of the substrate is a PVA film;
generating a heating source to modify the surface of the substrate, wherein a heating temperature to the substrate is between 100° C. and 500° C.; and
generating a plasma source for depositing a hydrophobic film in order to modify the surface of the substrate.

2. The surface modification method of the screen printing film as claimed in claim 1, wherein the step of generating the heating source is prior to, after, or simultaneous with the step of generating the plasma source.

3. The surface modification method of the screen printing film as claimed in claim 1, wherein a heating time of the heating source is between 1 second and 300 seconds.

4. The surface modification method of the screen printing film as claimed in claim 1, wherein a heating frequency of the heating source is between 1 time and 20 times.

5. The surface modification method of the screen printing film as claimed in claim 1, wherein the heating source comprises an infrared lamp exposure, an ultraviolet light exposure, a contact heating, or a heating through microwave or radio frequency electromagnet.

6. The surface modification method of the screen printing film as claimed in claim 1, wherein the plasma source comprises electron cyclotron resonance (ECR) or capacitance-coupled plasma (CCP).

7. The surface modification method of the screen printing film as claimed in claim 1, wherein a pressure of the plasma source is between 10⁻⁴ Torr and 1 Torr.

8. The surface modification method of the screen printing film as claimed in claim 1, wherein a reaction gas of the plasma source is at least one selected from the group consisting of fluorocarbon, hydrocarbon, oxygen and inert gases.

9. The surface modification method of the screen printing film as claimed in claim 8, wherein a flow of the inert gases is between 10% and 75% based on a total flow of the reaction gas.

10. The surface modification method of the screen printing film as claimed in claim 8, wherein the hydrophobic film comprises a multilayer structure including a fluorocarbon film and a diamond-like film.

11. The surface modification method of the screen printing film as claimed in claim 1, wherein a plasma coverage area of the plasma source is at least 0.1 m² or more.

12. The surface modification method of the screen printing film as claimed in claim 11, wherein the plasma coverage area of the plasma source is between 0.1 m² and 4 m².

13. A screen printing film being surface-modified by using the method as claimed in claim 1, characterised in that a main component of the screen printing film is hydroxyl group-free polyvinyl alcohol (PVA).

14. The screen printing film as claimed in claim 13, wherein a surface of the screen printing film is a hydrophobic multilayer film including a plasma-coated fluorocarbon film and a plasma-coated diamond-like film.

15. The screen printing film as claimed in claim 13, wherein a contact angle of the screen printing film with water is greater than 100 degrees.

16. The screen printing film as claimed in claim 13, wherein a contact angle of the screen printing film with water is less than 150 degrees.
